(19) United States
(12) Patent Application Publication
(10) Pub. No.: US 2024/0213416 A1
(43) Pub. Date: Jun. 27, 2024

(54) PATTERNING COLOR CONVERSION

(71) Applicant: VueReal Inc., Waterloo (CA)

(72) Inventor: Gholamreza Chaji, Waterloo (CA)

(73) Assignee: VueReal Inc., Waterloo, ON (CA)

(21) Appl. No.: 18/553,003

(22) PCT Filed: Apr. 1, 2022
(86) PCT No.: PCT/CA2022/050499

§ 371 Date: Sep. 28, 2023

Related U.S. Application Data
(60) Provisional application No. 63/169,608, filed on Apr. 1, 2021.

(51) Int. Cl. H01L 33/50; H01L 25/075; H01L 33/60

(52) U.S. Cl. CPC H01L 33/505; H01L 25/0753; H01L 33/60; H01L 2933/0041

(57) ABSTRACT

The present invention pertains to creating color conversion patterns in a display system. In particular it relates to a method of patterning a color conversion layer on a display surface. Further, multiple color conversion layers are used along with a color filter. In addition, different patterning modes are used to enable switches in different pixel circuits for different color conversion layers.

### FIELD OF THE INVENTION

The present invention pertains to creating color conversion patterns in a display system.

### SUMMARY

The present invention relates to a display system, the system comprising, a backplane, a light emitting device, and a patterned color conversion layer wherein the color conversion layer is patterned using a display light emitting device.

The present invention relates to a method of patterning color conversion layer on a display surface the method comprising, coating at least part of the surface of display with a first color conversion layer, turning on selected set of light emitting devices to cure part of said color conversion layer that is in the path of the light of the said light emitting devices, and cleaning the excess material.

### BRIEF DESCRIPTION OF THE DRAWINGS

The foregoing and other advantages of the disclosure will become apparent upon reading the following detailed description and upon reference to the drawings.

FIG. 1 shows a display system that includes a backplane and light emitting devices.

FIG. 2A shows an example where the backplane is populated with light emitting devices.

FIG. 2B shows a patterned color conversion layer.

FIG. 2C shows an example where another color conversion layer is coated on the top surface.

FIG. 2D shows the patterned color conversion layer.

FIG. 3 shows an example embodiment of the patterning switches.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION OF THE INVENTION

Unless defined otherwise, all technical and scientific terms used herein have the same meaning as commonly understood by one of ordinary skill in the art to which this invention belongs. As used in the specification and claims, the singular forms “a”, “an” and “the” include plural references unless the context clearly dictates otherwise. The term “comprising” as used herein will be understood to mean that the list following is non-exhaustive and may or may not include any other additional suitable items, for example one or more further feature(s), component(s) and/or element(s) as appropriate. The terms “device” and “micro device” and “optoelectronic device” are used herein interchangeably. It would be clear to one skill in the art that the embodiments described here are independent of the device size. The terms “donor substrate” and “temporal substrate” are used herein interchangeably. However, it is clear to one skilled in the art that the embodiments described herein are independent of the substrate. The terms “system substrate” and “receiver substrate” are used herein interchangeably. However, it is clear to one skill in the art that the embodiments described here are independent of substrate type.

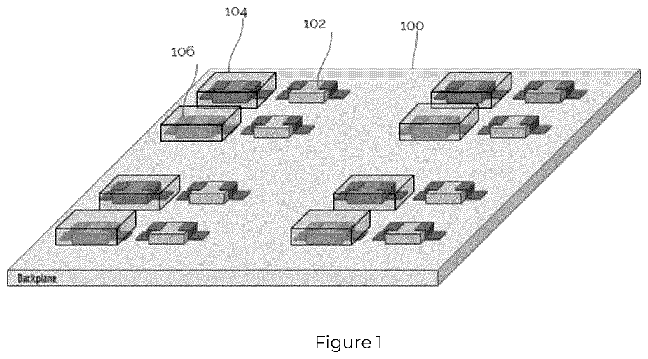

FIG. 1 shows a display system that includes a backplane 100 and light emitting devices 102. The backplane can include substrate and pixel circuits, connections, and pads. The light emitting diode devices 102 can be organic LED, mini LEDs, LEDs, and other types.

In one case, the pixel can include several subpixels and each subpixel can create a different wavelength (or color) 102. The subpixels can use color conversion layers 104 or 106 to make different colors.

One related embodiment to create the color conversion patterns 104 or 106 is to use display to turn on the intended pixel. The pixels cures the color conversion layer in the intended area.

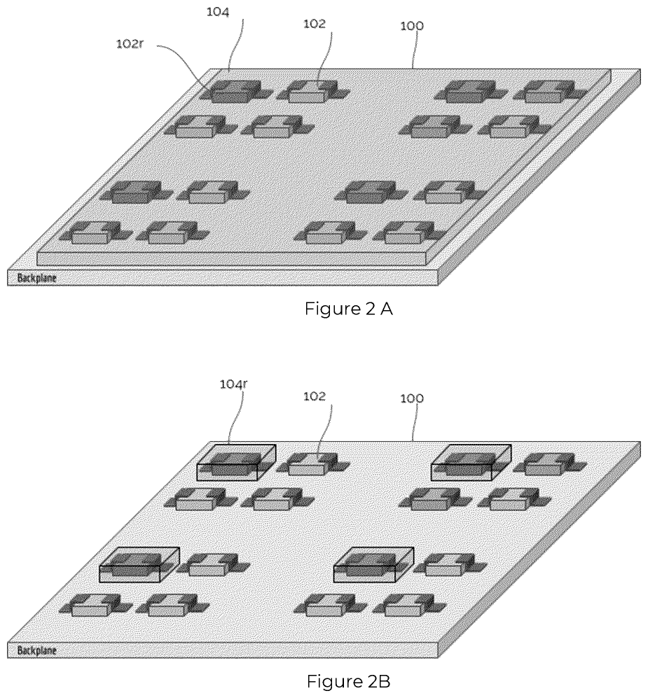

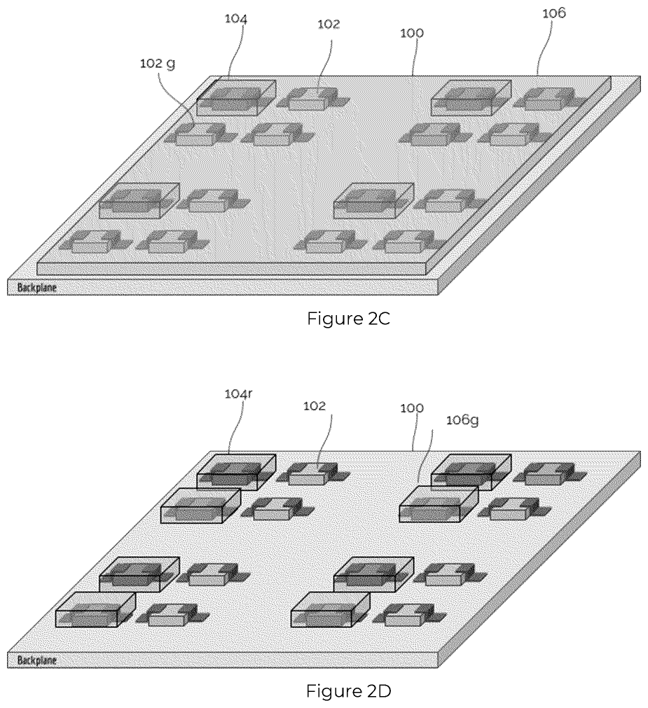

FIG. 2A shows an example where backplane 100 is populated with light emitting devices 102. A color conversion layer 104 is coated on the top surface. The coating can be done using spray, inkjet, or other methods. In one case, the intended light emitting devices 102r are turned ON. the color conversion layer around an on the device (in the path of the light) gets cured. The brightness of the devices are controlled so that the size of the cured area is within expected area. For example, the cured color conversion layer should not expand beyond the sub pixel area. In another case, the duration is also controlled so that the shape of the color conversion layer is controlled. In one case, controlling the emission of a light emitting device and its duration will make the color conversion layer as a half sphere with a light emitting device at the center of the half sphere. Here, the brightness can be low so that it cures the layers close to the light emitting device slower and so the top layers have the chance to get cured. The duration of the ON time can be extended till the intended size of the sphere is achieved. The intended size is smaller than the sub pixel from the sides and thickness is larger than a value that achieves a minimum conversion efficiency. After that, the excess materials are removed. Extra cleaning and curing processes can be done. The color conversion layer can be a combination of different layers such as color conversion and color filter. FIG. 2B shows the patterned color conversion layer 104r.

FIG. 2C shows an example where another color conversion layer 106 is coated on the top surface. The coating can be done using spray, inkjet or other methods. In one case, the intended light emitting devices 102g are turned ON. The color conversion layer around and/or on the device (in the path of the light) gets cured. After that, the excess materials are removed. Extra cleaning and curing processes can be done. The color conversion layer can be a combination of different layers such as color conversion and color filter.

FIG. 2D shows the patterned color conversion layer 106g. The process can be repeated to develop more patterned color conversion layers.

In one related case, the defects can be analyzed before coating color conversion layers. The pixels are mapped to each color and during patterning of each color conversion layer, the related mapped subpixel will turn on.

The color conversion layer can be a mix of color conversion particles (quantum dots or phosphorus or other forms of materials) and photoresist material sensitive to the light emitting device wavelength.

The space between the color conversion layer can be filled with reflector or opaque materials to prevent the light from leaking to other devices and also to improve the contrast ratio.

The backplane can have a patterning mode that can turn on a set of emissive devices with the brightness needed for patterning. Here, the pixel can have a switch that connects the emissive devices to a fixed or programmable bias when the pixel is in the patterning mode. There can be different patterning modes to enable the switches in different pixel circuits for different color conversion layers. For example, there can be red patterning signal, green patterning signal, or blue patterning signal which in turn connect the emissive devices associated with red, green or blue to the bias signal. In another related case, the backplane can have shorting bars to turn the devices or a test jig can be used. The challenge with this method is the pattern is fixed and so one cannot program each pixel independently to adjust the brightness or select the color conversion layer. In another related case, the dataline are connected to a set of patterning signals through switches. In this case, the patterning signal is connected to one pixel circuit at a time while other pixel circuits sharing the same signal are connected to or programmed with an off signal which turns off the pixel. In one related method, the intensity of the emissive devices are measured prior to patterning process and proper patterning signal is selected for each pixel. During the patterning, the selected patterning signal for a pixel is applied to the pixel. In another related case, the intensity of the pixel is measured during the patterning and the pixel patterning signal is adjusted till it meets the required intensity.

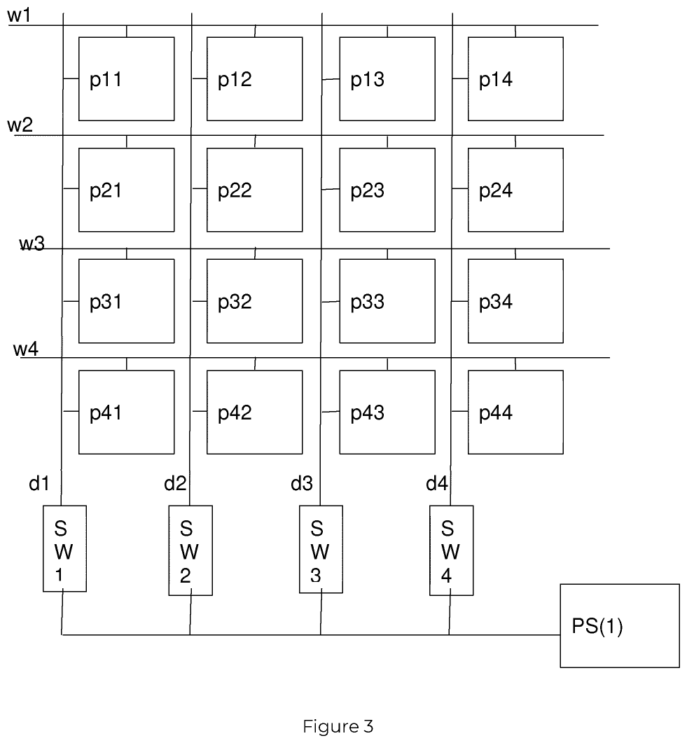

FIG. 3 shows an example embodiment of the patterning switches. Here a selected array of pixels (p11, p12, . . . p43, p44) that are connected to data lines (d1, d2, d3, d4) and write signal (w1, w2, w3, w4). The data lines (d1, . . . d4) are connected to a patterning signal “PS” through a set of switches (S1, S2, . . . ). In one operation mode, one selected switch (S1 for example) connects one data line the patterning signal (PS) and the other switches (S2, S3, S4) connect the datalines (d2, d3, d4) to the off signal. Here the write signal (w1) for one column is selected, and the pixel connected to the selected write (w1) is programmed with the patterning signals or off signals. The switch's configuration can change for the next programming, and another write signal can be activated. The process continues till all the pixels are programmed with the proper patterning signals. In another patterning mode, the switches only connect or disconnect the patterning signals (PS). Here, the switches are selected and either a signal or patterning bias is applied to the patterning signal (PS). The patterning and off signals and patterning switches can operate based on the defects, and intensity of the pixel measured in advance.

The present invention relates to a method of patterning color conversion layer on a display surface the method comprising, coating at least part of the surface of display with a first color conversion layer, turning on selected set of light emitting devices to cure part of said color conversion layer that is in the path of the light of the said light emitting devices, and cleaning the excess material. The figures and their description describe all the details as part of the method as they apply to the system description.

While the present disclosure is susceptible to various modifications and alternative forms, specific embodiments or implementations have been shown by way of example in the drawings and are described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

1. A display system, the system comprising: a backplane, a light emitting device, and a patterned color conversion layer wherein the color conversion layer is patterned using a display light emitting device.

2. The display system of claim 1, wherein the color conversion layer comprises a color conversion material and a photoresist material sensitive to a light of light emitting devices.

3. The display system of claim 1, wherein the color conversion layer is a stack of different layers such as color conversion or color filter.

4. The display system of claim 1, wherein the backplane turns the light emitting devices selectively to a brightness needed for curing the color conversion layer.

5. The display system of claim 4, wherein the backplane is turned on by a curing mode embedded in the backplane.

6. The display system of claim 4, wherein the backplane has a shorting bar for turning ON a set of the light emitting devices.

7. The display system of claim 4, wherein the brightness of the devices is controlled to keep a size of cured area within a set area.

8. The display system of claim 7, wherein the cured color conversion layer does not expand beyond a sub pixel area.

9. The display system of claim 4, wherein a brightness duration is also controlled so that a shape of the color conversion layer is controlled.

10. The display system of claim 9, wherein controlling the emission of light emitting device and its duration makes the color conversion layer as a half sphere with light emitting device at the center of the half sphere.

11. The display system of claim 9, wherein the brightness is low to cure the layers close to the light emitting device slower while top layers get cured first.

12. The display system of claim 10, wherein the duration of the ON time is extended till the intended size of the sphere is achieved.

13. The display system of claim 3, wherein a space between the color conversion layers are filled with reflector or opaque materials prevent the light from leaking to other devices and also to improve a contrast ratio.

14. The display system of claim 1, wherein the backplane a patterning mode that can turn ON a set of emissive devices with the brightness needed for patterning and wherein a pixel has a switch that connects the emissive devices to a fixed or programmable bias when the pixel is in the patterning mode.

15. The display system of claim 14, wherein there are different patterning modes to enable switches in different pixel circuits for different color conversion layers.

16. The display system of claim 14, wherein the backplane has shorting bars to turn ON the devices or a test jig is used.

17. The display system of claim 14, wherein datalines are connected to a set of patterning signals through switches wherein a patterning signal is connected to one pixel circuit at a time while at latest one or more other pixel circuits sharing the same signal are connected to or programmed with an OFF signal which turns OFFthe pixel.

18. The display system of claim 17, wherein an intensity of the emissive devices is measured prior to the patterning process and a proper patterning signal is selected for each pixel wherein during the patterning, the selected patterning signal for a pixel is applied to the pixel.

19. The display system of claim 17, wherein the intensity of the pixel is measured during the patterning and the pixel patterning signal is adjusted till it meets a required intensity.

20. The display system of claim 17, wherein a selected array of pixels are connected to datalines and a write signal wherein further the datalines are connected to a patterning signal through a set of switches.

21. The display system of claim 20, wherein in one operation mode, one selected switch connects one data line the patterning signal and the other switches connect the datalines to an OFF signal and wherein further, the write signal for one column is selected, and the pixel connected to the selected write signal is programmed with the patterning signals or OFF signals.

22. The display system of claim 21, a switch configuration is changed for the next programming, and another write signal is activated and this process continues till all the pixels are programmed with the proper patterning signals.

23. The display system of claim 20, wherein in another patterning mode, the switches only connect or disconnect the patterning signals wherein further, the switches are selected and either an OFF signal or a patterning bias is applied to the patterning signal.

24. The display system of claim 23, wherein the patterning and OFF signals and patterning switches are operated based on the defects, and intensity of the pixel measured in advance.

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)
